(19) United States
(12) Patent Application Publication
(10) Pub. No.: US 2013/0048070 A1
(43) Pub. Date: Feb. 28, 2013

(54) TUNNEL PHOTOVOLTAIC

(71) Applicants: Arash Hazeghi, San Francisco, CA (US); Vivek Subramanian, Orinda, CA (US)

(72) Inventors: Arash Hazeghi, San Francisco, CA (US); Vivek Subramanian, Orinda, CA (US)

(21) Appl. No.: 13/585,798

(22) Filed: Aug. 14, 2012

Related U.S. Application Data
(60) Provisional application No. 61/527,845, filed on Aug. 26, 2011.
(60) Provisional application No. 61/528,710, filed on Aug. 29, 2011.
(60) Provisional application No. 61/560,741, filed on Nov. 16, 2011.

(51) Int. Cl. H01L 31/06; H01L 31/18

(52) U.S. Cl. 136/256; 438/98; 257/E31.055

(57) ABSTRACT

A tunneling photovoltaic (“TPV”) device using a high-κ dielectric as a tunneling layer is disclosed. The TPV includes a P-type doped silicon semiconductor substrate. Formed on its surface is an interfacial layer, between the semiconductor substrate and the high-κ tunneling layer. Formed on the high-κ tunneling layer is an electrode layer, or stack electrode layer, receiving charge carriers that tunnel through the tunneling layer, generating a current when the device is illuminated by light. The tunneling layer can be hafnium oxide or other suitable high-κ dielectrics. A method of fabricating a high-κ TPV is also disclosed. The TPV device according to the embodiments has improved internal quantum efficiency.

### CROSS-REFERENCE TO RELATED APPLICATIONS

This application claims priority to the following provisional patent applications: Ser. No. 61/527,845, filed on Aug. 26, 2011; Ser. No. 61/528,710, filed on Aug. 29, 2011; and Ser. No. 61/560,741, filed on Nov. 16, 2011. Priority to these provisional applications is expressly claimed, and the disclosures of the provisional applications are hereby incorporated herein by reference in their entirety.

### FIELD

The present patent document relates generally to photovoltaic cells. In particular, the present patent document relates to a tunneling photovoltaic device and a method of manufacturing the same.

### BACKGROUND

Photovoltaic (“PV”) cells are semiconductor devices that generate power by turning photons into charge carriers and electric current which can be harvested. This electrical energy can be immediately used or stored for future use. Given the infinite source of solar energy, PV cells are a promising device for generating electricity at low cost and with low to zero emissions.

In order to generate electricity from light, photons are absorbed by a semiconductor, such as silicon (“Si”), gallium arsenide (“GaAs”), or germanium. A p-n junction is formed in a typical PV device, wherein P-type doped semiconductor material, having an abundance of holes, and an N-type doped semiconductor material, having an abundance of electrons, are electrically connected at a junction. An incident photon generates electron-hole pairs (“EHP”) in the conduction and valance bands of the semiconductor. The EHPs are then separated by an electric field formed at the p-n junction and collected at electrodes on either side of the p-n junction. This gives rise to a current that can be used to drive a load, which is connected to the electrodes through an external circuit.

Two factors limit the efficiency of conventional p-n junction PV cells. The first factor is material absorption. Most commercial PV cells use silicon as the light-absorbing material. The Si bandgap, which is approximately 1.12 eV at room temperature, makes it difficult to capture the long-wavelength portion of the solar spectra associated with infrared. Furthermore silicon is an indirect bandgap material which reduces the absorption coefficient. The second factor limiting efficiency is carrier collection efficiency. As EHPs split at the junction and drift towards the contacts for collection, a large number of them recombine and lose their energy to heat, also known as phonons. A greater number of EHPs can be formed by increasing the thickness of the PV cell, which result in greater light absorption. To absorb more light, the cell needs to have a thickness on the order of tens of microns. However, this is at odds with carrier transport since the longer the EHPs need to travel before they reach the contacts, the higher the chances of recombination of the EHPs, in which case the energy absorbed from light is dissipated as heat.

Although the PV industry has been battling these two limiting factors for decades, both still limit the practical internal quantum energy conversion efficiency of Si PVs to less than about 28% in the laboratory and less than about 25% in commercial use. Higher efficiency PV cells, having up to approximately 40% efficiency, have been made of materials other than Si, for example group III-V elements of the periodic table. An example is GaAs—which has a more efficient direct bandgap than Si (an indirect bandgap semiconductor)—in a sophisticated hetero-junction structure. However, the high cost of these materials and complex structures prevent commercial applications.

Metal-insulator-semiconductor (“MIS”) structures for PV applications offer an alternative to p-n junction devices. Use of a MIS for PV applications instead of the more traditional p-n junction was demonstrated in 1970's. A MIS PV with an efficacy of 17.6% was fabricated by Godfrey et al., 655 mV open-circuit voltage, 17.6% efficient silicon MIS solar cells, 34 Appl. Phys. Lett. 790-93 (Jun. 1, 1979), which is fully incorporated herein by reference. This was higher than a standard PV at the time. In 1997, a MIS PV with an efficiency of 18.5% was reported by Metz et al., 18.5% efficient first-generation MIS inversion-layer silicon solar cells, 1997 Photovoltaic Specialists Conference 31-34 (Sep. 29 to Oct. 3, 1997), which is fully incorporated herein by reference. The relative lack of efficiency of such MIS PV structures is primarily due to use of silicon dioxide (SiO₂) as the insulator in the tunnel barrier. SiO₂ has a large energy band offset to the silicon conduction band (φ_{b}=3.1 eV) which constitutes a large potential barrier for electrons. Therefore to have effective tunneling and a high short-circuit current (“ISC”), a very thin SiO₂ layer is needed. Given that the above efficiencies were obtained with already very thin SiO₂ layers of approximately ten to fifteen angstroms, it is impractical to manufacture these cells at a large scale or further boost efficiency by reducing the SiO₂ thickness.

### SUMMARY

A tunneling photovoltaic is disclosed. In an embodiment the tunneling photovoltaic comprises a semiconductor substrate, a tunneling layer comprising a high-κ dielectric formed on the semiconductor substrate, first electrode formed on the tunneling layer, and a second electrode formed on the semiconductor substrate.

In another embodiment, the tunneling layer comprises hafnium oxide.

In another embodiment, the tunneling layer comprises a high-κ dielectric selected from the group consisting of titanium dioxide, aluminum oxide, lanthanum oxide, zirconium oxide, tantalum oxide, nitrided hafnium silicate, and zirconium silicate.

In another embodiment, the tunneling layer is between ten and fifty angstroms thick.

In another embodiment, the tunneling layer comprises a high-κ dielectric that has an effective electron mass at room temperature less than an effective electron mass of silicon dioxide at room temperature.

In another embodiment, the semiconductor substrate comprises silicon. In another embodiment, the silicon substrate comprises P-type doped silicon.

In another embodiment, the first electrode comprises aluminum.

In another embodiment, the tunneling photovoltaic further includes an interfacial layer formed on the semiconductor substrate and the tunneling layer is formed on the interfacial layer. In another embodiment, the interfacial layer comprises a compound selected from the group consisting of silicon oxide, silicon nitride, and oxynitride.

A method of fabricating a tunneling photovoltaic cell is also disclosed. In an embodiment, the method comprises providing a semiconductor substrate, forming a tunneling layer comprising a high-κ dielectric on the semiconductor substrate, forming a first electrode layer on the tunneling layer; and forming a second electrode layer on the semiconductor substrate.

In another embodiment of the method, the tunneling layer comprises hafnium oxide.

In another embodiment of the method, the tunneling layer comprises a high-κ dielectric selected from the group consisting of titanium dioxide, aluminum oxide, lanthanum oxide, zirconium oxide, tantalum oxide, nitrided hafnium silicate, and zirconium silicate.

In another embodiment of the method, the tunneling layer is between ten and fifty angstroms thick.

In another embodiment of the method, the tunneling layer comprises a high-κ dielectric that has an effective electron mass at room temperature less than an effective electron mass of silicon dioxide at room temperature.

In another embodiment of the method, the semiconductor substrate comprises silicon. In another embodiment, the silicon substrate comprises P-type doped silicon.

In another embodiment of the method, the first electrode comprises aluminum.

In another embodiment, the method further includes forming the interfacial layer on the semiconductor substrate wherein the tunneling layer is formed on the interfacial layer. In another embodiment of the method, the interfacial layer comprises a compound selected from the group consisting of silicon oxide, silicon nitride, and oxynitride.

The above and other preferred features described herein, including various novel details of implementation and combination of elements, will now be more particularly described with reference to the accompanying drawings and pointed out in the claims. It will be understood that the particular methods and apparatuses are shown by way of illustration only and not as limitations of the claims. As will be understood by those skilled in the art, the principles and features of the teachings herein may be employed in various and numerous embodiments without departing from the scope of the claims.

### BRIEF DESCRIPTION OF THE DRAWINGS

The accompanying drawings, which are included as part of the present specification, illustrate the presently preferred embodiments and, together with the general description given above and the detailed description of the preferred embodiments given below, serve to explain and teach the principles of the present invention.

FIG. 1A illustrates the layers of a tunneling photovoltaic (“TPV”) device.

FIG. 1B illustrates a TPV device connected to a circuit for test or operation.

FIG. 2 illustrates an exemplary flow for the fabrication of a TPV device.

FIG. 3 illustrates an energy band diagram for a TPV cell at thermal equilibrium and no incident light.

FIG. 4 illustrates an energy band diagram for a TPV cell under illumination in a short-circuit configuration.

FIG. 5 illustrates an energy band diagram for a TPV cell under illumination in an open-circuit configuration.

The figures are not necessarily drawn to scale and the elements of similar structures or functions are generally represented by like reference numerals for illustrative purposes throughout the figures. The figures are only intended to facilitate the description of the various embodiments described herein; the figures do not describe every aspect of the teachings disclosed herein and do not limit the scope of the claims.

### DETAILED DESCRIPTION

A high-κ tunneling photovoltaic (“TPV”) apparatus is disclosed, as well as a method of manufacturing a high-κ TPV. Each of the features and teachings disclosed herein can be utilized separately or in conjunction with other features and teachings. Representative examples utilizing many of these additional features and teachings, both separately and in combination, are described in further detail with reference to the attached drawings. This detailed description is merely intended to teach a person of skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings.

In the following description, for purposes of explanation only, specific nomenclature is set forth to provide a thorough understanding of the present invention. However, it will be apparent to one skilled in the art that these specific details are not required to practice the present invention.

The various features of the representative examples and the dependent claims may be combined in ways that are not specifically and explicitly enumerated in order to provide additional useful embodiments of the present teachings. It is also expressly noted that all value ranges or indications of groups of entities disclose every possible intermediate value or intermediate entity for the purpose of original disclosure, as well as for the purpose of restricting the claimed subject matter. It is also expressly noted that the dimensions and the shapes of the components shown in the figures are designed to help to understand how the present teachings are practiced, but not intended to limit the dimensions and the shapes shown in the examples.

The various embodiments described herein relate to the field of PV cells. In an embodiment, a tunneling layer with specific properties is integrated with a MIS stack to form a TPV device. Specifically, PV cells that incorporate a tunneling layer in an MIS structure to improve efficiency. In p-n junction-based PV cells, electrons and holes are extracted by drift/diffusion. By contrast, charge carriers are extracted by quantum mechanical tunneling through the insulator layer in a TPV. The charge carriers may be electrons or holes, depending on the particular TPV structure. Since the tunneling occurs very quickly, typically on the order of picoseconds, the optically-generated carriers will not have a chance to recombine as they are extracted rapidly. This is because recombination typically occurs within the range of microseconds to milliseconds, much more slowly than tunneling. Additionally, absence of the p-n junction used in standard PV cells reduces recombination in the space charge region, further boosting the efficiency.

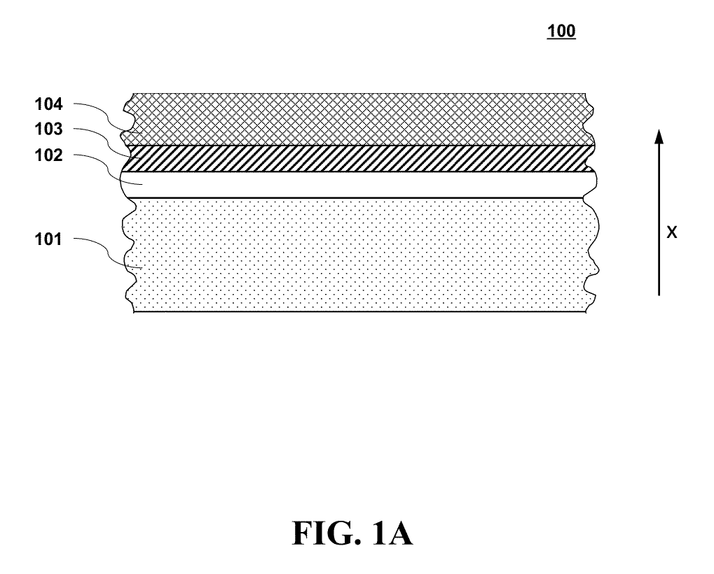

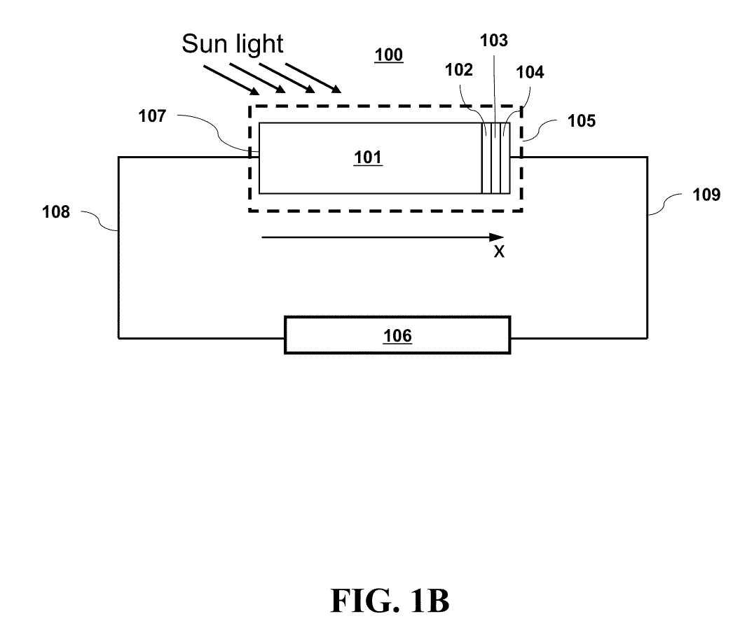

FIG. 1A is an illustration of a TPV device 100 according to an embodiment. Note that FIG. 1A is an illustration representing the relationship between adjacent layers of the TPV device and is not drawn to scale. Substrate 101 is a P-type doped silicon semiconductor substrate. Substrate 101 may be single-crystal, poly-crystalline, or amorphous silicon. Substrate 101 acts as the absorption layer for photons, where EHPs are formed, which absorption layer may be up to several hundred microns thick. Interfacial layer 102 is a thin layer that passivates the surface and/or terminate the dangling bonds of substrate 101. The purpose of interfacial layer 102 is to reduce the density of surface defects that act as interface traps trapping electrons.

Interfacial layer 102 comprises SiO_{X} in an embodiment. Interfacial layer 102 can also comprise Si₃N₄, other nitride, oxynitride, chemical oxide, or similar compounds. Interfacial layer 102 may be intentionally doped to achieve a certain flat-band voltage (“VFB”) and adjust the zero-bias field.

Tunnel layer 103 is preferably a thin layer of high-κ material. In an embodiment, tunnel layer 103 comprises hafnium oxide (HfO₂). In a preferred embodiment, tunnel layer 103 can be less than fifty angstroms. For example, the high-κ layer 103 can be between fifteen and fifty angstroms. For higher efficiency, the tunnel layer should have two properties that improve efficiency: (a) a low conduction band offset with the substrate conduction band, to allow high tunneling current; and (b) the tunnel material has a low effective electron mass, in general, less than 0.5 mₒ. Use of high-κ dielectrics as the tunnel layer in the TPV cell satisfies both requirements.

High-K materials, including hafnium oxide, have a smaller conduction band offset (φ_{b}) when compared to the conduction band of silicon and other semiconductors, and thus allow high levels of tunnel current with a larger physical thickness compared to the SiO₂ used in the prior art. Therefore high-κ layer 103 does not have to be scaled as aggressively as would a SiO₂ layer for providing a high tunnel current.

In addition to a lower barrier, high-κ materials such as hafnium oxide have a lower tunneling effective mass compared to SiO₂, which makes tunneling more efficient for a given physical thickness. For example the tunneling effective mass m_{eff} of hafnium oxide is approximately 0.2 mₒ, where mₒ is the free electron mass. By contrast the effective mass m_{eff} of SiO₂ is approximately 0.4 mₒ.

The high-κ dielectric allows efficient tunneling of electrons (holes) while providing an efficient barrier to recombination. The ISC can be modulated by altering the tunneling layer thickness and choice of material, which optimizes on the material's low band offset to the substrate material and low electron effective mass. Furthermore, ISC can be maximized independent of the VOC, which provides an additional degree of freedom in design and optimizing the output power.

Electrode layer 104, adjacent to tunnel layer 103 in this embodiment, is a collector layer having a low workfunction, for example, a metal, including aluminum, or doped cap layers, including titanium nitride (TiN). By using an electrode with appropriate workfunction, the VOC can be modulated, independent of ISC. The VOC can be tuned by the electrode workfunction and semiconductor doping level. The appropriate electrode workfunction is achieved in several different ways. An appropriate electrode workfunction can be achieved by using metals or alloys with low workfunction. Also, by using doped semiconductors and/or engineered capping layers containing materials such as titanium nitride, tantalum nitride, or similar compounds, interface charges can be created at the interface between the electrode layer 104 and the tunneling layer 103 to alter the workfunction. Similar techniques can also create interface charges at the interface between the tunneling layer 103 and the interfacial layer to alter the workfunction. Combinations of the above can be used as desired.

Furthermore, known absorption-enhancement technologies, for example antireflective coatings (AR), surface texturing, encapsulation, or passivation, can be readily applied to the TPV as well. Use of these techniques will further boost the cell efficiency. The TPV cell can thus effectively improve efficiency over known PVs without a significant increase in cost.

FIG. 1B is an illustration of a TPV device 100 according to an embodiment, under illumination and connected to a load 106, for example for testing or real-world operation. The TPV device 100 includes a substrate 101, interfacial layer 102, tunnel layer 103, and electrode layer 104. A back contact 107 is affixed to semiconductor substrate 101 and connected to conductor 108. Back contact 107 may be any material or stack of materials suitable for providing a low resistivity to the substrate 101, such as aluminum or titanium. Electrode layer 104 is connected to electrode 109. Each of electrodes 108 and 109 are connected to either side of a load 106. During real-world operation, sunlight will illuminate TPV device 100, creating a voltage potential that will drive a current through load 106. For purposes of testing, load 106 may be an open circuit, whereby the open circuit open-circuit voltage (“VOC”) may be measured. Load 106 may also be a short circuit, whereby the short-circuit current (“ISC”) may be measured.

According to an alternative embodiment, semiconductor substrate 101 can N-type doped silicon substrate, rather than P-type doped silicon substrate. The use of an N-type doped semiconductor substrate may alter the selection of certain materials used to fabricate the interfacial layer, tunneling layer, and electrode layer. However, according to the embodiment, the tunneling layer is still a high-κ dielectric, for example hafnium oxide (HfO₂).

According to another embodiment, other substrates with band gaps which enhance light absorption are used, such as Group III-V materials of the periodic table. Such III-V materials include gallium arsenide (GaAs) and indium phosphide (InP).

According to alternative embodiments, other high-κ dielectric compounds can be used in place of hafnium oxide (HfO₂). Suitable compounds include metal oxides with a large bandgap and a high dielectric constant, such as titanium dioxide (TiO₂), aluminum oxide (Al₂O₃), lanthanum oxide (La₂O₃), zirconium oxide (ZrO₂), tantalum oxide (Ta₂O₅), nitrided hafnium silicates (HfSiON), silicates such as zirconium silicate (ZrSiO₄), and other compounds with similar properties.

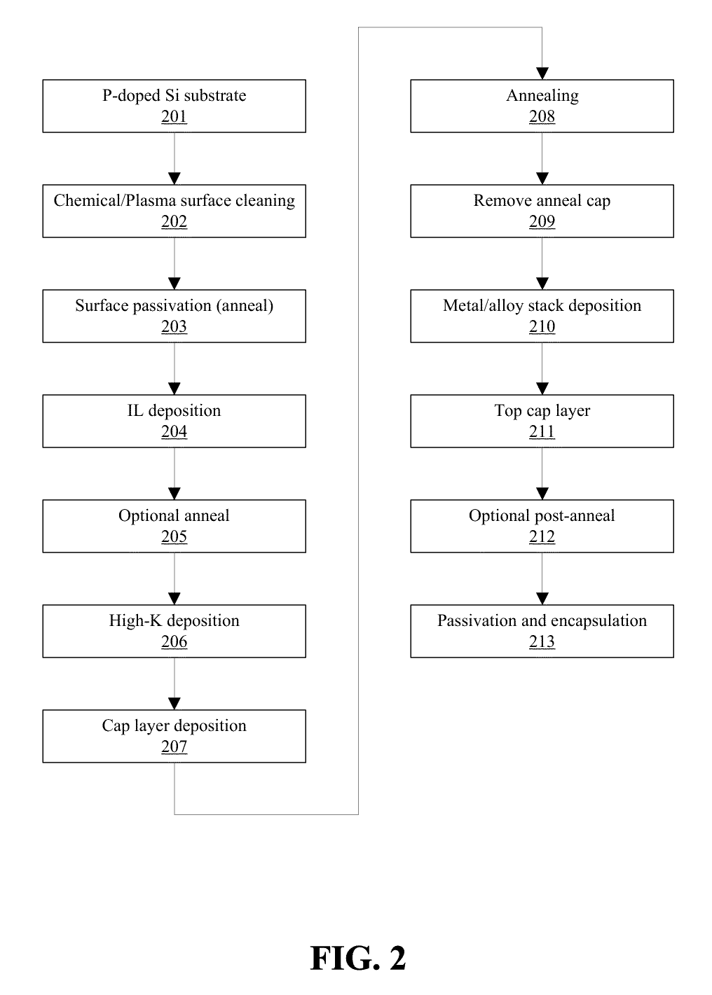

FIG. 2 is an exemplary flow illustrating the fabrication of a TPV device according to an embodiment. At step 201, a P-doped silicon substrate having a smooth, polished surface is provided to act as a photon absorption layer. This absorption layer may be up to several hundred microns thick. The substrate may be any suitable crystalline, amorphous, or poly-crystalline silicon. At step 202, the P-doped silicon substrate is cleaned using a chemical or dry clean process. Such processes include exposure to HF, HCl, and piranha solutions, or different plasmas such as Ar or O₂ plasmas in a vacuum chamber. At step 203 the surface may be passivated through annealing. At step 204, a very thin interfacial layer is formed on the substrate to passivate the substrate surface and/or terminate the dangling bonds of the substrate surface. This interfacial layer may be up to fifty angstroms thick, but preferably is less than fifty angstroms thick. The interfacial layer can comprise any of SiO_{X}, Si₃N₄, other nitride, oxynitride, chemical oxide, or similar compounds. The interfacial layer can be deposited using atomic layer deposition (“ALD”), by plasma deposition, or chemical methods as appropriate to the chosen interfacial layer material. Step 205 is an optional anneal step performed once the interfacial layer is formed. The annealing may be at moderate temperatures, for example 300-400° C., in an inert ambient, and annealing may be through a process such as forming gas annealing (“FGA”). The thickness of the interfacial layer (IL) can be adjusted later in the process by scavenging its content using a special cap layer such as lanthanum cap. At step 206 the high-κ tunneling layer is deposited using ALD. This tunneling layer may be up to fifty angstroms thick, but preferably is in the range of fifteen to fifty angstroms thick. For the structure of FIGS. 1A and 1B, step 206 comprises deposition of a layer of hafnium oxide (HfO₂) using ALD or another suitable process. Alternative high-κ materials forming the tunneling layer may also be deposited using ALD or another suitable process at step 206. The tunneling layer has a low conduction band offset from the semiconductor substrate conduction band, and an effective electron mass of preferably less than 0.5 mₒ, which both improve power conversion efficiency of the TPV cell. In the ALD process, the thickness of the deposited layer is controlled by the number of cycles and the density of the film is controlled by the ALD conditions. In an embodiment, the thickness of the ALD-deposited tunneling layer is between fifteen and fifty angstroms. A capping layer may optionally be added to the structure at step 207 prior to annealing step 208 to prevent diffusion of certain species, including oxygen that will degrade the stack by creating vacancies in the structure. This capping layer maybe removed after annealing. The capping layer may be, for example, a layer of lanthanum (La). Another possible function for the capping layer is scavenging of the interfacial layer (IL) contents to tune its thickness. At step 208, the structure, including the high-κ layer, is annealed at moderate temperatures, for example 300-450° C., in an inert ambient, through a process such as FGA, to restructure the surface and rearrange the broken bonds in order to improve the quality of the film and the surface. After annealing, if the anneal cap was added at step 207, it is removed at step 209. At step 210 the top electrode layer is formed by evaporation, sputtering, or ALD, depending on the material used for the top electrode. A conductive material with the appropriate workfunction forms the electrode. The electrode may be a standard metal, including aluminum, an alloy, a doped layer, including titanium nitride (TiN), a doped semiconductor such as polysilicon, or a transparent conductive oxide (TCO). Step 211 is the formation of a capping layer on top of the high-κ layer but below the electrode stack, or on top of the electrode stack. The capping layer can include materials such as titanium nitride or tantalum nitride. This capping layer further tunes the workfunction of the electrode stack by inducing charges or dipoles at the interface of the tunneling later and capping layer, or at the interface of the tunneling layer and interfacial layer. At step 212, a final anneal step may be performed after the electrode layer is deposited, for example at a temperature less than 400° C. At step 213, the TPV may be passivated, textured, and/or encapsulated in order to enhance light absorption. The TPV may also be configured to operate with front, back, or side illumination in accordance with the described flow.

With the disclosed optimized deposition process, which includes ALD accompanied by various surface preparation and interface layers, as well as pre- and post-deposition annealing, the surface trap charge density is lowered so that generated carriers are not lost to recombination in the surface charge traps prior to tunneling. This results in the described TPV cell having a greater internal quantum efficiency than a conventional silicon PV cell. Additionally, VOC and ISC can be independently tuned to maximize power output.

According to an alternative embodiment, step 201 comprises providing an N-doped silicon substrate. Use of an N-doped silicon substrate will require other steps to be somewhat altered to take account of tunneling by holes through the tunneling layer, and their subsequent collection at the metal/alloy stack electrode, as well as the collection of electrons at the back contact electrode that is connected to the N-doped silicon substrate.

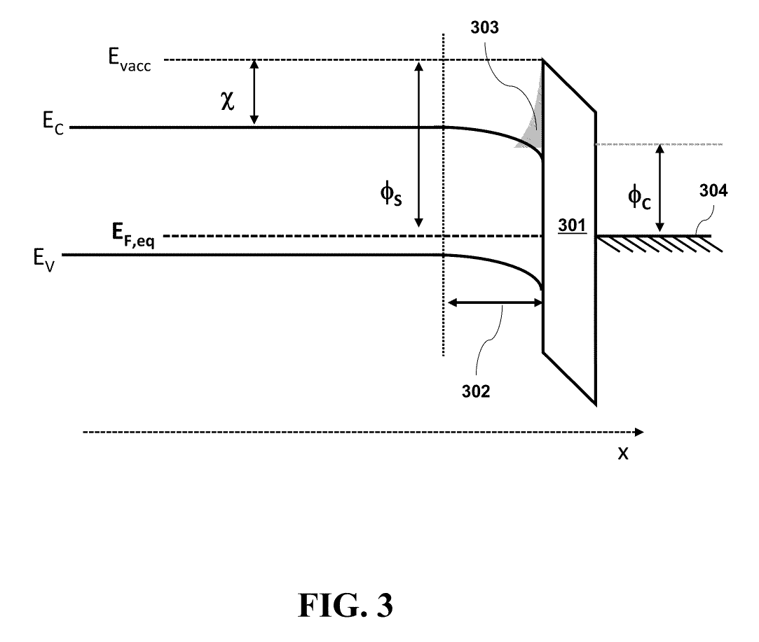

FIG. 3 is an energy band diagram for a TPV cell according to an embodiment. The TPV cell is oriented in the x-direction as indicated, and is at thermal equilibrium and no incident light. A high-κ tunneling layer 301 separates, physically in the TPV cell, the semiconductor layer, on the left of tunneling layer 301, from the electrode layer, on the right of tunneling layer 301. Under conditions of thermal equilibrium, the semiconductor layer Fermi level E_{F,eq} is aligned with the electrode/collector layer Fermi level 304, resulting in zero net current (J=0) and zero external voltage (V=0). The electric field is due to the differences in the workfunction between the electrode/collector and semiconductor layers, resulting in a depletion region 302 in the semiconductor layer. The electron distribution 303 at thermal equilibrium illustrates the distribution of thermal electrons in the vicinity of the tunneling layer 301, a greater number of thermal electrons closer to tunneling layer 301, with their number quickly tapering off further from the tunneling layer 301, in the negative x-direction in FIG. 3.

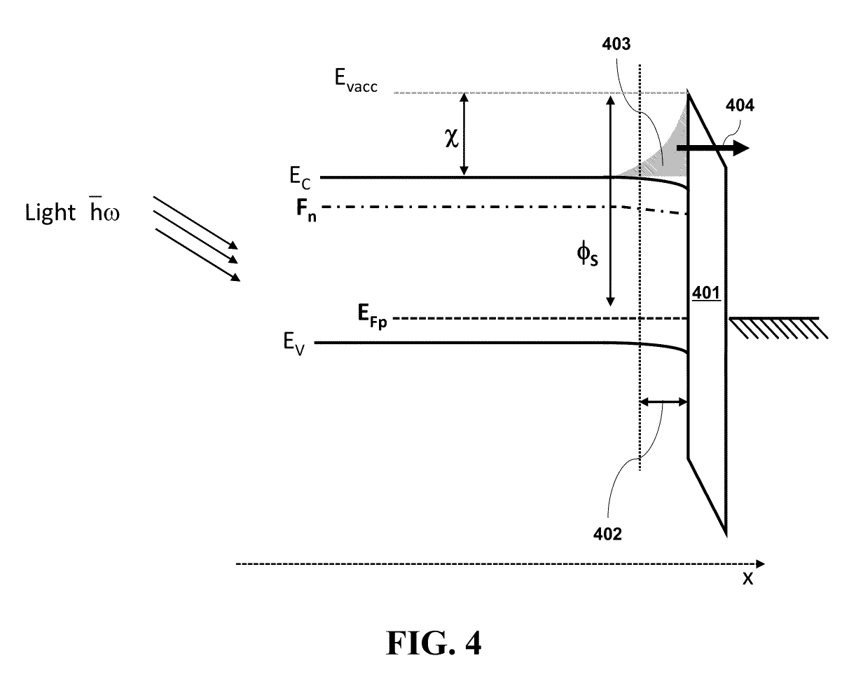

FIG. 4 is an energy band diagram for the TPV cell of FIG. 3 under illumination by light and in a short-circuit configuration to measure ISC. The light has split the electron and hole quasi-Fermi levels, Fₙ and E_{Fp} respectively. The generated electrons at the junction, the distribution of which are represented by distribution 403, tunnel through the tunneling layer 401 with little loss, giving their energy to the external circuit. The direction of tunneling is illustrated conceptually with arrow 404. The optically generated electrons accumulate at the surface, reducing the width of the depletion region 402 and reducing band bending of the conduction band E_{C} and valence band E_{V} of the semiconductor near tunneling layer 401. This, in turn, increases the electric field across the tunneling layer 401, enabling a large flux of electrons to escape the semiconductor through tunneling layer 401, generating a large ISC. The small energy band offset χ between the semiconductor and the high-κ tunneling layer 401 allows a sustained high injection current while keeping the thickness of tunneling layer 401 at a reasonable limit for manufacturing. For example, if the manufacturing limit is a tunneling layer of twenty angstroms, then use of a high-κ tunneling layer according to an embodiment will sustain a higher injection current than a prior art silicon dioxide tunneling layer of twenty angstroms.

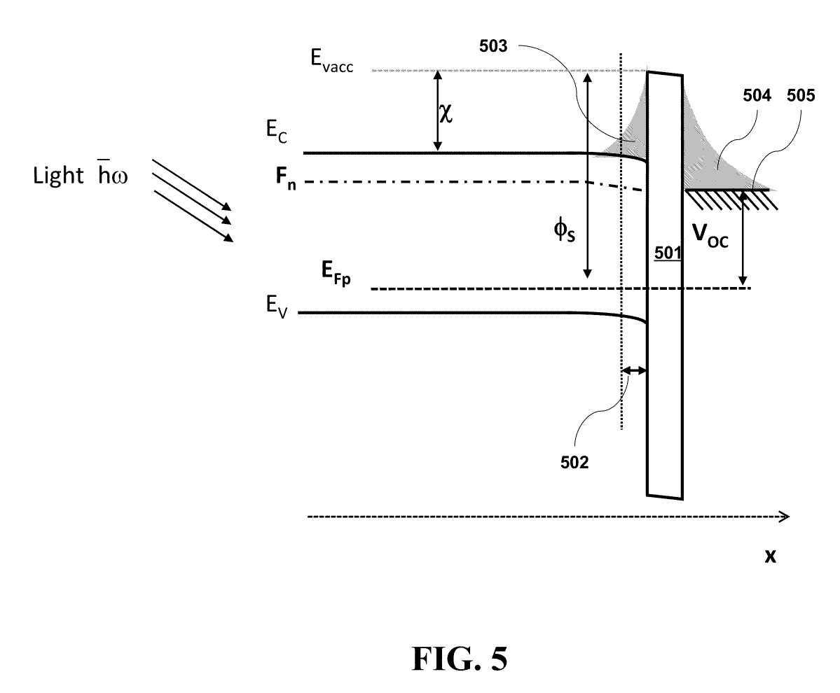

FIG. 5 is an energy band diagram for the TPV cell of FIG. 3 under illumination by light and in an open-circuit configuration to measure VOC. The light has split the electron and hole quasi-Fermi levels, Fₙ and E_{Fp} respectively. Due to the open circuit, the net current across the tunneling layer 501 must be zero. This constraint causes the electrode Fermi level 505 to raise to match the electron quasi-Fermi level of the semiconductor substrate Fₙ. The electric field across the tunneling layer 501 is small and the band-bending of the conduction band E_{C} and valence band E_{V} of the semiconductor near tunneling layer 501 has been suppressed. The flux of electrons from the electrode in the semiconductor is equal to the flux of electrons from the semiconductor to the electrode. Distribution 503 represents the distribution of optical electrons on the semiconductor substrate side of tunneling layer 501. Distribution 504 represents the distribution of electrons on the electrode side of tunneling layer 501. The resultant voltage difference V_{OC} between the electrode Fermi level 505 and the hole quasi-Fermi levels E_{Fp} is the output open-circuit voltage VOC. VOC may be tuned by altering the electrode, and hence altering its workfunction, without changing the semiconductor doping and reaching values close to the semiconductor energy gap.

The TPV cell illustrated in FIGS. 3, 4, and 5 is a minority carrier device, and FIGS. 3, 4, and 5 are illustrated for a P-type substrate, which relies on electron tunneling as the minority carrier. The TPV cell can also be made from a N-type substrate, relying on tunneling by holes as the minority carriers.

Although various embodiments have been described with respect to specific examples and subsystems, it will be apparent to those of ordinary skill in the art that the concepts disclosed herein are not limited to these specific examples or subsystems but extends to other embodiments as well. Included within the scope of these concepts are all of these other embodiments as specified in the claims that follow.

We claim:

1. A tunneling photovoltaic, comprising:
a semiconductor substrate;
a tunneling layer comprising a high-κ dielectric formed on the semiconductor substrate;
a first electrode formed on the tunneling layer; and
a second electrode formed on the semiconductor substrate.

2. The tunneling photovoltaic of claim 1, wherein the tunneling layer comprises hafnium oxide.

3. The tunneling photovoltaic of claim 1, wherein the tunneling layer comprises a high-κ dielectric selected from the group consisting of titanium dioxide, aluminum oxide, lanthanum oxide, zirconium oxide, tantalum oxide, nitrided hafnium silicate, and zirconium silicate.

4. The tunneling photovoltaic of claim 1, wherein the tunneling layer is between ten and fifty angstroms thick.

5. The tunneling photovoltaic of claim 1, wherein the tunneling layer comprises a high-κ dielectric that has an effective electron mass at room temperature less than an effective electron mass of silicon dioxide at room temperature.

6. The tunneling photovoltaic of claim 1, wherein the semiconductor substrate comprises silicon.

7. The tunneling photovoltaic of claim 6, wherein the semiconductor substrate comprises P-type doped silicon.

8. The tunneling photovoltaic of claim 1, wherein the first electrode comprises aluminum.

9. The tunneling photovoltaic of claim 1, further comprising:
an interfacial layer formed on the semiconductor substrate, and;
wherein the tunneling layer is formed on the interfacial layer.

10. The tunneling photovoltaic of claim 9, wherein the interfacial layer comprises a compound selected from the group consisting of silicon oxide, silicon nitride, and oxynitride.

11. A method of fabricating a tunneling photovoltaic cell, comprising:
providing a semiconductor substrate;
forming a tunneling layer comprising a high-κ dielectric on the semiconductor substrate;
forming a first electrode layer on the tunneling layer; and
forming a second electrode layer on the semiconductor substrate.

12. The method of fabricating a tunneling photovoltaic cell of claim 11, wherein the tunneling layer comprises hafnium oxide.

13. The method of fabricating a tunneling photovoltaic cell of claim 11, wherein the tunneling layer comprises a high-κ dielectric selected from the group consisting of titanium dioxide, aluminum oxide, lanthanum oxide, zirconium oxide, tantalum oxide, nitrided hafnium silicate, and zirconium silicate.

14. The method of fabricating a tunneling photovoltaic cell of claim 11, wherein the tunneling layer is between ten and fifty angstroms thick.

15. The method of fabricating a tunneling photovoltaic cell of claim 11, wherein the tunneling layer comprises a high-κ dielectric that has an effective electron mass at room temperature less than an effective electron mass of silicon dioxide at room temperature.

16. The method of fabricating a tunneling photovoltaic cell of claim 11, wherein the semiconductor substrate comprises silicon.

17. The method of fabricating a tunneling photovoltaic cell of claim 16, wherein the semiconductor substrate comprises P-type doped silicon.

18. The method of fabricating a tunneling photovoltaic cell of claim 11, wherein the first electrode comprises aluminum.

19. The method of fabricating a tunneling photovoltaic cell of claim 11, wherein the tunneling layer is formed on an interfacial layer, the method further comprising:
forming the interfacial layer on the semiconductor substrate.

20. The method of fabricating a tunneling photovoltaic cell of claim 19, wherein the interfacial layer comprises a compound selected from the group consisting silicon oxide, silicon dioxide, silicon nitride, and oxynitride.
